(19) United States
(12) Patent Application Publication
(10) Pub. No.: US 2018/0012763 A1
(43) Pub. Date: Jan. 11, 2018

(54) DOPING METHOD, DOPING APPARATUS, AND SEMICONDUCTOR ELEMENT MANUFACTURING METHOD

(71) Applicant: TOKYO ELECTRON LIMITED, Tokyo (JP)

(72) Inventors: Hirokazu UEDA, Yamanashi (JP); Masahiro OKA, Yamanashi (JP); Yuuki KOBAYASHI, Miyagi (JP); Yasuhiro SUGIMOTO, Yamanashi (JP)

(73) Assignee: TOKYO ELECTRON LIMITED, Tokyo (JP)

(21) Appl. No.: 15/539,224

(22) PCT Filed: Dec. 14, 2015
(86) PCT No.: PCT/JP2015/084883

§ 371 Date: Jun. 23, 2017

(30) Foreign Application Priority Data
Dec. 24, 2014 (JP) 2014-260604

(51) Int. Cl. H01L 21/223; H01J 37/32; H01L 29/66; H01L 21/02

(52) U.S. Cl. CPC H01L 21/2236; H01L 21/02057; H01J 37/32715; H01L 29/66803; H01J 37/32266; H01J 37/3244; H01J 2237/3365; H01J 2237/335

(57) ABSTRACT

Provided is a doping method for doping by injecting a dopant into a processing target substrate. According to this doping method, a value of bias electric power supplied during a plasma doping processing is set to a predetermined value on premise of a washing processing to be performed after a plasma doping, and plasma is generated within a processing vessel using microwaves so as to perform the plasma doping processing on the processing target substrate hold on a holding pedestal in the processing vessel.

### TECHNICAL FIELD

The exemplary embodiments described herein relate to a doping method, a doping apparatus, and a semiconductor element manufacturing method.

### BACKGROUND

A semiconductor element such as, for example, a large scale integrated circuit (LSI) or a metal oxide semiconductor (MOS) transistor, is manufactured by performing processes such as, for example, doping, etching, chemical vapor deposition (CVD), and sputtering, on a semiconductor substrate (wafer) serving as a processing target substrate.

Here, as a method of performing doping, there are an ion doping method using an ion injection device and a plasma doping method performed by injecting radicals or ions of dopants into the surface of a processing target object by directly using plasma. Further, since a demand for a method of uniformly injecting dopant impurities into a doping target object, such as, for example, a fin field effect transistor (FinFET) type semiconductor element having a three-dimensional structure, irrespective of an uneven portion on the three-dimensional structure (conformal doping) has been very strong, a plurality of doping methods using plasma have been tried and reported.

For example, in a doping method using a doping processing apparatus (i.e., plasma doping), there is a technique of performing doping on a whole three-dimensional structure by mainly generating ionic plasma and then scattering the generated ionic plasma.

In addition, as a recent attempt, a method of uniformly injecting a dopant into a side wall of a FinFET has been introduced as a method of conformally injecting the dopant into the side wall of the FinFET, which is called ion assisted deposition and doping (IADD). Also, IADD is a method of performing additional ion oblique irradiation on an As (arsenic) film formed using plasma.

Here, when doping is performed on a doping target object such as, for example, a FinFET type semiconductor element having a three-dimensional structure, there has been a demand for a high coverage that, in respective portions of the doping target object, equalizes doping depths from the surfaces of the respective portions or dopant concentrations, that is, high conformality in doping.

### PRIOR ART DOCUMENT

### Non-Patent Document

Non-Patent Document 1: Hirokazu Ueda, Peter L. G. Ventzek, Masahiro Oka, Masahiro Horigome, Yuuki Kobayashi, Yasuhiro Sugimoto, Toshihisa Nozawa, and Satoru Kawakami, “Conformal Doping of Topographic Silicon Structures Using a Radial Line Slot Antenna Plasma Source,” Journal of Applied Physics 115, 214904 (2014)

### DISCLOSURE OF THE INVENTION

### Problems to be Solved

However, in the related art, there has been a problem in that doping may not be conformally performed on a doping target object such as, for example, a FinFET type semiconductor element having a three-dimensional structure.

For example, in the ion doping of the IADD in the related art, doping may not be performed completely conformally (uniformly) because the amount of ion irradiation for a portion that is hidden as the three-dimensional structure of the FinFET type semiconductor element becomes a stereoscopic barrier becomes smaller than that in the top portion of the FinFET. Referring to a more detailed example, when doping is performed using ion beams, the ion beams are irradiated at an angle of 45 degrees relative to the surface of the substrate of the FinFET type semiconductor element in order to dope all of a top portion, a side portion, and a bottom portion of each fin of the FinFET type semiconductor element. Thereafter, the ion beams are irradiated at an angle of 135 degrees, in other words, at an angle of 45 degrees from the opposite side. As a result, when the fin has a certain height, the irradiated ions do not reach the bottom portion and a region close to the bottom portion in a height direction of the fin in the side portion.

Further, in order to overcome the disadvantage of this ion doping, in the IADD of the related art, there has been reported a method of forming an As-containing thin film, which is formed using plasma at low temperature, on the surface of a fin in advance, and irradiating an ion component by applying a bias electric field so as to cause As atoms to be knocked in Si (fin body). However, a purpose to conformally dope both the top portion and the side portion of the fin body has not been completely achieved.

In addition, in the technique of performing doping on the whole three-dimensional structure by scattering generated ionic plasma, a plasma doping method is provided that is characterized by randomly irradiating dopants (ion species) generated by plasma to the surface of a three-dimensional structure by an ion extraction mechanism that is made of an extension plate. However, test data represented by this method suggests that a thickness of an amorphous layer (disordered Si crystal layer including dopants) formed on the surface of the three-dimensional structure is conformal, but does not indicate that both the top portion and the side portion of the fin body can be conformally doped with uniform dopant concentration.

In other words, in the doping method using the above-described doping processing apparatus, the layer thickness of a pre-amorphous layer generated as a result of doping is only uniform, and conformality is not achieved only by a doping processing. Further, for example, in the FinFET type semiconductor element having the three-dimensional structure in the above-described related art, the doping depth and concentration of dopants injected at a position of the top portion, the doping depth and concentration of dopants injected at a position of the side portion, and the doping depth and concentration of dopants injected at a position of the bottom portion are not uniform, and as a result, doping is not conformally performed.

In this regard, the present inventors have found that conformality may be achieved by performing an annealing processing right after doping. However, a method of achieving conformality when the annealing processing cannot be performed right after doping has not been established so far. For example, in the case where a mask such as, for example, a resist having no heat resistance, exists on a doped element or in the case where contamination elements may diffuse from a remaining film generated by doping when a heat treatment is performed right after doping, conformality cannot be achieved by the annealing processing.

The present disclosure has been made in consideration of the above circumstance, and provides a doping method, a doping apparatus, and a semiconductor element manufacturing method that may implement conformal doping even when a heat treatment of a processing target substrate cannot be performed right after doping.

### Means to Solve the Problems

The doping method, the doping apparatus, and the semiconductor element manufacturing method according to an exemplary embodiment includes: setting a value of bias electric power supplied during a plasma doping processing to a value at which the dopant concentration of the top portion of the processing target substrate and the dopant concentration of the side portion of the processing target substrate become substantially equal, when a washing processing is performed under a predetermined condition after the plasma doping processing; and generating plasma within a processing vessel using microwaves so as to perform the plasma doping processing on the processing target substrate held on a holding pedestal.

### Effect of the Invention

According to the exemplary embodiment, even when a heat treatment on a processing target substrate cannot be performed right after doping, conformal doping can be implemented.

### BRIEF DESCRIPTION OF THE DRAWINGS

FIG. 1 is a schematic perspective view illustrating a portion of a FinFET type semiconductor element, which is a semiconductor element manufactured by a doping method and a doping apparatus according to a first exemplary embodiment.

FIG. 2 is a schematic cross-sectional view illustrating a principal portion of the doping apparatus according to the first exemplary embodiment.

FIG. 3 is a flowchart illustrating schematic processes of the doping method according to the first exemplary embodiment.

FIG. 4 is a view illustrating a doping amount for a FinFET type semiconductor element in the case of performing doping using a plasma doping processing.

FIG. 5 is a graph illustrating a relative ratio of an aspect ratio in a FinFET type semiconductor element to a concentration of a dopant to be injected.

FIG. 6A is a graph illustrating a relationship among a value of bias electric power supplied in a plasma doping processing, a dopant concentration of a processing target substrate after the plasma doping processing, and a dopant concentration of the processing target substrate after performing sulfuric-acid and hydrogen-peroxide mixture (SPM) washing after the plasma doping processing.

FIG. 6B is a view illustrating schematic positions of a top portion and a side portion of the FinFET type semiconductor element illustrated in FIG. 6A.

FIG. 7 is an enlarged graph illustrating a dopant concentration after the SPM washing in the graph illustrated in FIG. 6A.

FIG. 8 is a graph for explaining a relationship between a temperature applied to a holding pedestal and a dopant concentration after the SPM washing.

FIG. 9 is a flowchart illustrating a flow of a method for manufacturing the semiconductor element according to the first exemplary embodiment.

### DETAILED DESCRIPTION TO EXECUTE THE INVENTION

Hereinafter, exemplary embodiments of a doping method, a doping apparatus, and a semiconductor element manufacturing method of the present disclosure will be described in detail with reference to the accompanying drawings. Further, the present disclosure is not limited by the exemplary embodiments disclosed herein. In addition, respective embodiments may be appropriately combined within a range that does not contradict the processing contents.

A doping method according to an exemplary embodiment is a method of performing doping by injecting a dopant into a processing target substrate, and the method includes a plasma doping processing step including: setting a value of bias electric power supplied in a plasma doping processing to a predetermined value on premise of a washing processing to be performed after a plasma doping; and generating plasma within a processing vessel using microwaves so as to perform the plasma doping processing on the processing target substrate held on a holding pedestal in the processing vessel.

Further, in the doping method according to the exemplary embodiment, the value of the bias electric power in the plasma doping processing step may be set to a value that when the washing processing is performed after the plasma doping processing, a dopant concentration of a top portion and a dopant concentration of a side portion in the processing target substrate become substantially equal.

Further, the doping apparatus according to the exemplary embodiment includes: a processing vessel; a gas supply unit configured to supply a doping gas and an inert gas for plasma excitation to the processing vessel; a holding pedestal disposed within the processing vessel and configured to hold the processing target substrate having a three-dimensional structure; a plasma generation mechanism configured to generate plasma within the processing vessel using microwaves; and a controller configured to set a value of bias electric power to a predetermined value on premise of a washing processing to be performed after a plasma doping processing and to control the plasma to be generated within the processing vessel so as to perform the plasma doping processing on the processing target substrate held on the holding pedestal.

In addition, the doping apparatus according to the exemplary embodiment further includes a storage unit configured to store, as a condition of the plasma doping processing, a value of bias electric power at which a dopant concentration of a top portion of the processing target substrate and a dopant concentration of a side portion of the processing target substrate are substantially equal to each other when the washing processing is performed after the plasma doping. The controller controls the plasma generation mechanism to generate the plasma within the processing vessel based on a condition stored in the storage unit so that the plasma doping processing is performed on the processing target substrate held on the holding pedestal.

In addition, the semiconductor element manufacturing method according to the exemplary embodiment includes: an acquiring step of acquiring, as a condition of a plasma doping processing, a predetermined value of bias electric power on premise of a washing processing to be performed after the plasma doping processing; a plasma doping processing step of performing the plasma doping processing on a processing target substrate while supplying the predetermined value of bias electric power acquired by the acquiring step; and a washing processing step of performing the washing processing on the processing target substrate on which the plasma doping processing has been performed.

Further, in the acquiring step of the semiconductor element manufacturing method according to the exemplary embodiment, as the predetermined value, a value of bias electric power is acquired at which a dopant concentration of a top portion of the processing target substrate and a dopant concentration of a side portion of the processing target substrate are substantially equal to each other after the washing processing is performed.

Further, in the semiconductor element manufacturing method according to the exemplary embodiment, in the acquiring step, the predetermined value of the bias electric power determined in association with a predetermined condition of the washing processing is acquired, and the plasma doping processing step may be performed while bias electric power in a range of 100 W to 400 W is supplied as the predetermined value.

### First Exemplary Embodiment

In a first exemplary embodiment, on the premise that a washing processing is performed after a doping processing is performed on a processing target substrate having a three-dimensional structure, a doping condition is adjusted such that the dopant concentration of a top portion and the dopant concentration of a side portion in the processing target substrate after the washing processing become equal to each other. In particular, conformal doping added with the influence of the washing processing is implemented by adjusting a value of bias electric power supplied to a holding pedestal that holds the processing target substrate during the plasma doping processing.

Implementation of conformal doping by adding the influence on the dopant concentration by the washing processing and adjusting the condition of the plasma doping processing is enabled due to the fact that the chemical resistance of a side portion of a fin is high in a semiconductor element manufactured using the plasma doping processing. An example of a structure of a doping apparatus according to the first exemplary embodiment, an example of a doping method, the details of adjusting the condition for the plasma doping processing according to the first exemplary embodiment, and an example of the semiconductor element manufacturing method according to the first exemplary embodiment will be described sequentially.

Example of FinFET Type Semiconductor Element

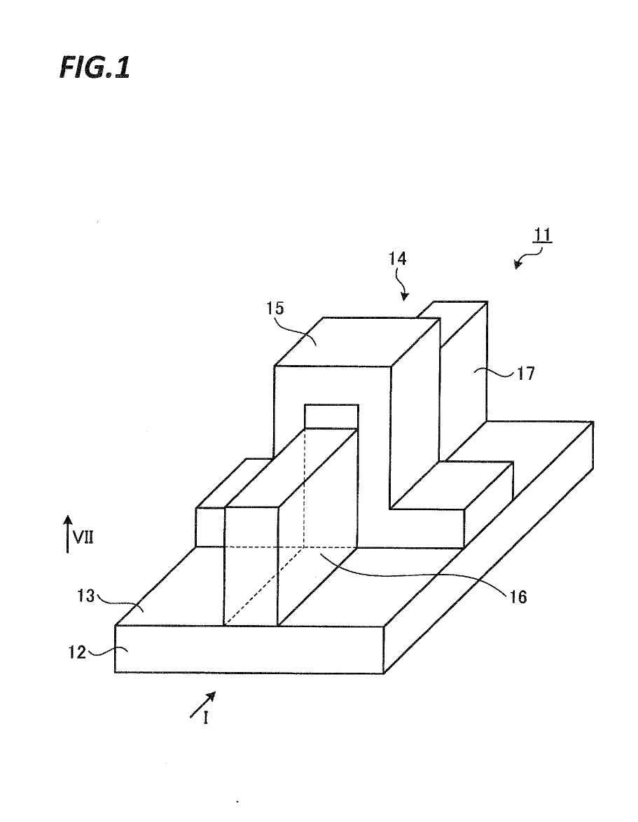

FIG. 1 is a schematic perspective view illustrating a portion of a FinFET type semiconductor element, which is a semiconductor element manufactured by a doping method and a doping apparatus, according to the first exemplary embodiment. Referring to FIG. 1, in the FinFET type semiconductor element 11 manufactured by the doping method and the doping apparatus according to the first exemplary embodiment of the present disclosure, a fin 14 protruding long upward from a main surface 13 of a silicon substrate 12 is formed. The extending direction of the fin 14 is a direction indicated by arrow I in FIG. 1. A portion of the fin 14 is substantially rectangular when viewed in the direction of arrow I which is the lateral direction of the FinFET type semiconductor element 11. A gate 15 extending in a direction orthogonal to the extending direction of the fin 14 is formed so as to cover a portion of the fin 14. A source 16 is formed in the front side of the formed gate 15, and a drain 17 is formed in the deep side. Doping is performed by the plasma generated using microwaves on the shape of the fin 14, that is, the surface of the portion protruding upward from the main surface 13 of the silicon substrate 12.

In addition, although not illustrated in FIG. 1, depending on the semiconductor element manufacturing process, a photoresist layer may be formed before doping is performed. The photoresist layer is formed at a predetermined distance on the side of the fin 14, for example, in a portion located in the lateral direction of the surface in FIG. 1. The photoresist layer extends in the same direction as the fin 14 and is formed to protrude long upward from the main surface 13 of the silicon substrate 12.

Example of Doping Apparatus According to First Exemplary Embodiment

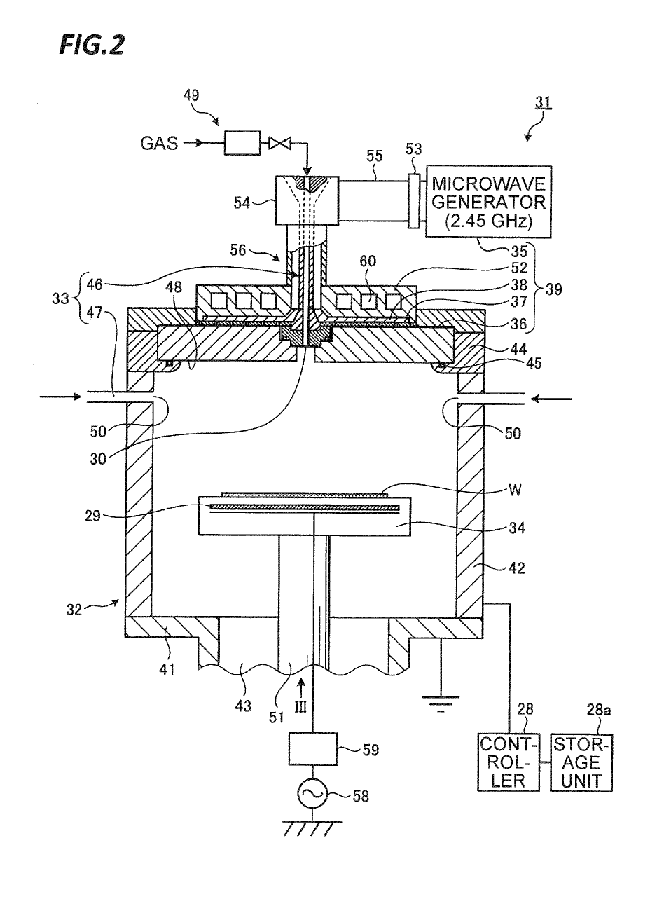

FIG. 2 is a schematic cross-sectional view illustrating a principal portion of the doping apparatus according to the first exemplary embodiment. Further, in FIG. 2, hatching of some members is omitted from the viewpoint of facilitating the understanding. Additionally, in this exemplary embodiment, a vertical direction on the paper surface in FIG. 2 corresponds to a vertical direction of the doping apparatus.

Referring to FIG. 2, the doping apparatus 31 includes: a processing vessel 32 configured to perform doping on a processing target substrate W therein; a gas supply unit 33 configured to supply a gas for plasma excitation or a doping gas into the processing vessel 32; a disc-shaped holding pedestal 34 configured to hold the processing target substrate W thereon; a plasma generation mechanism 39 configured to generate plasma within the processing vessel 32 using microwaves; a pressure adjustment mechanism configured to adjust pressure in the processing vessel 32; a bias electric power supply mechanism configured to supply bias electric power of an alternating current to the holding pedestal 34; and a controller 28 configured to control an operation of the whole doping apparatus 31. The controller 28 performs a control of the whole doping apparatus 31 such as, for example, a gas flow rate in the gas supply unit 33, a pressure in the processing vessel 32, and bias electric power supplied to the holding pedestal 34. The controller 28 is connected to a storage unit 28a that stores a doping processing condition such as, for example, bias electric power.

The processing vessel 32 includes a bottom portion 41 positioned at the lower side of the holding pedestal 34, and a sidewall 42 extending upward from the outer periphery of the bottom portion 41. The sidewall 42 has a substantially cylindrical shape. The bottom portion 41 of the processing vessel 32 includes an exhaust hole 43 for exhaust provided to penetrate a portion thereof. The upper side of the processing vessel 32 is opened and is configured to be sealable by a lid portion 44 disposed on the upper side of the processing vessel 32, a dielectric window 36 (to be described later), and an O-ring 45 as a sealing member interposed between the dielectric window 36 and the lid portion 44.

The gas supply unit 33 includes a first gas supply unit 46 that injects a gas toward the center of the processing target substrate W and a second gas supply unit 47 that injects a gas from the outside of the processing target substrate W. A gas supply hole 30a that supplies a gas in the first gas supply unit 46 is provided at a position which lies in the radial center of the dielectric window 36, and retreats inward of the dielectric window 36 from the bottom surface 48 of the dielectric window 36, which is a facing surface that faces the holding pedestal 34. The first gas supply unit 46 supplies an inert gas for plasma excitation or a doping gas while adjusting the flow rate by a gas supply system 49 connected to the first gas supply unit 46. The second gas supply unit 47 includes a plurality of gas supply holes 50 that supply an inert gas for plasma excitation or a doping gas to the processing vessel 32, provided in a part of an upper side of the sidewall 42. The plurality of gas supply holes 50 are provided equidistantly in a circumferential direction. The first gas supply unit 46 and the second gas supply unit 47 are supplied with the same kind of the inert gas for plasma excitation or the doping gas from the same gas source. Further, other gases may be supplied from the first gas supply unit 46 and the second gas supply unit 47 depending on a request or a control content, and the flow ratio thereof, or the like may be adjusted.

In the holding pedestal 34, a high frequency wave power source 58 for radio frequency (RF) bias is electrically connected to an electrode within the holding pedestal 34 via a matching unit 59. The high frequency power source 58 is capable of outputting high frequency waves of, for example, 13.56 MHz at a predetermined electric power (bias power). The matching unit 59 includes a matcher for matching between the impedance of the high frequency power source 58 side and the impedance of a load side such as, mainly, the electrode, the plasma, and the processing vessel 32. The matcher includes a blocking condenser for self-bias generation. Further, the supplying of the bias electric power to the holding pedestal 34 varies appropriately as needed. The controller 28 controls the bias electric power of an alternating current supplied to the holding pedestal 34 as a bias electric power supply mechanism.

The holding pedestal 34 is capable of holding a processing target substrate W thereon by an electrostatic chuck (not illustrated). The holding pedestal 34 is supported by a cylindrical insulative support 51 that extends vertically upward from the lower side of the bottom portion 41. The exhaust hole 43 is provided through a portion of the bottom portion 41 of the processing vessel 32 along the outer periphery of the cylindrical support 51. An exhaust device (not illustrated) is connected to the lower side of the annular exhaust hole 43 via an exhaust pipe (not illustrated). The exhaust device includes a vacuum pump such as, for example, a turbo molecular pump. By the exhaust device, the space within the processing vessel 32 may be decompressed to a predetermined pressure. The controller 28 adjusts the pressure within the processing vessel 32 by, for example, the control of exhaust by the exhaust device serving as a pressure adjustment mechanism.

The plasma generation mechanism 39 is provided outside the processing vessel 32, and includes a microwave generator 35 that generates microwaves for plasma excitation. The plasma generation mechanism 39 also includes the dielectric window 36 that is disposed at a position facing the holding pedestal 34 and introduces the microwaves generated by the microwave generator 35 into the processing vessel 32. Further, the plasma generation mechanism 39 includes a slot antenna plate 37 that is provided with a plurality of slots 40 and is disposed above the dielectric window 36 to radiate the microwaves to the dielectric window 36. Further, the plasma generation mechanism 39 includes a dielectric member 38 that is disposed above the slot antenna plate 37 and propagates the microwaves, which have been introduced by a coaxial waveguide 56 (to be described later), in a radial direction.

The microwave generator 35 having a matching 53 is connected to an upper portion of the coaxial waveguide 56 that introduces the microwaves, via a mode converter 54 and a waveguide 55. For example, TE-mode microwaves generated by the microwave generator 35 are converted into TEM-mode microwaves by the mode converter 54 via the waveguide 55, which are propagated via the coaxial waveguide 56. As the frequency of the microwaves generated by the microwave generator 35, for example, 2.45 GHz is selected.

The dielectric window 36 is substantially disc-shaped, and made of a dielectric. Specific examples of the material of the dielectric window 36 may include quartz or alumina.

The slot antenna plate 37 is in a form of a thin plate and a disc. Here, the slot antenna plate 37 may be a radial line slot antenna.

The microwaves generated by the microwave generator 35 are propagated through the coaxial waveguide 56. The microwaves spread radially outward from a region interposed between a cooling jacket 52 and the slot antenna plate 37, and are radiated from the plurality of slots 40 provided in the slot antenna plate 37 to the dielectric window 36. The cooling jacket 32 includes a circulation path 60 that allows a coolant to circulate therein, and performs a temperature adjustment of, for example, the dielectric member 38. The microwaves transmitted through the dielectric window 36 cause an electric field to be generated just below the dielectric window 36, so that plasma is generated within the processing vessel 32.

In this manner, the plasma generation mechanism has a dielectric window 36 that is exposed within the processing vessel 32 and is provided at a position facing the holding pedestal 34. Here, the shortest distance between the dielectric window 36 and the processing target substrate W held on the holding pedestal 34 is set to 5.5 cm to 15 cm.

When a microwave plasma is generated in the doping apparatus 31, a so-called plasma generation region where the electron temperature of plasma is a relatively high is formed just below the bottom surface 48 of the dielectric window 36, specifically in a region located several centimeters below the bottom surface 48 of the dielectric window 36. In addition, in a region located at a lower side in the vertical direction of the dielectric window 36, a so-called plasma diffusion region where the plasma generated in the plasma generation region diffuses is formed. The plasma diffusion region is a region where the electron temperature of plasma is relatively low, and the plasma doping processing, that is, doping is performed in this region. Further, when the microwave plasma is generated in the doping apparatus 31, the electron density of the plasma becomes relatively high. Then, efficient doping, specifically, for example, shortening of the doping time may be achieved since a so-called plasma damage is not imparted to the processing target substrate W during the doping, and also owing to a high electron density of the plasma.

Here, in the inductively coupled plasma (ICP or the like) of a general plasma source, since the generated amount of high energy ions becomes much larger as compared to the radicals and low energy ion components in the plasma, the plasma irradiation damage to the processing target substrate also increases. In this regard, by using the microwave plasma, radicals and low energy ion components may be efficiently generated in a high pressure zone where a pressure favorable for conformal doping formation is 100 mTorr or more. Also, the radicals (active species) are not affected by a plasma electric field since the microwave plasma is used. In other words, since the radicals are electrically neutral, the plasma irradiation damage to the processing target substrate may be overwhelmingly reduced as compared to ions.

Example of Doping Method According to First Exemplary Embodiment

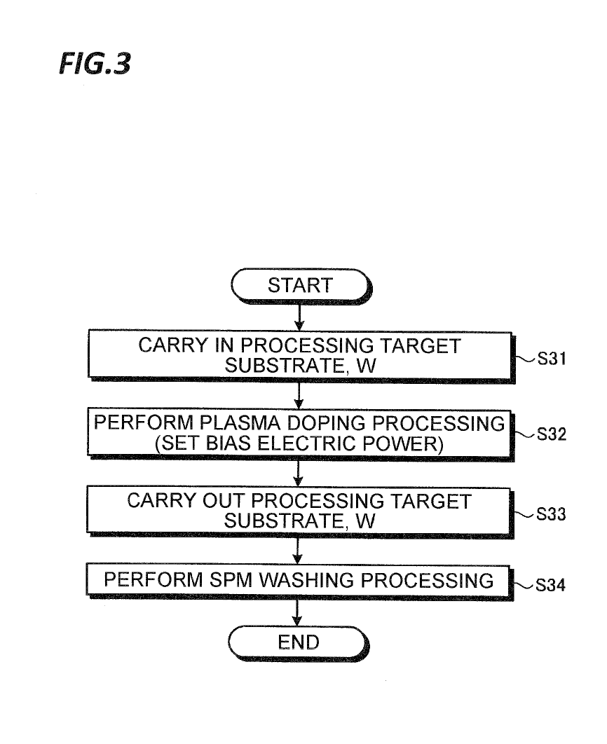

Next, a method of doping a processing target substrate W using such a doping apparatus will be described. FIG. 3 is a flowchart illustrating schematic processes of the doping method according to the first exemplary embodiment.

First, as illustrated in FIG. 3, a processing target substrate W on which a plasma doping processing is performed is carried into the doping apparatus 31 and disposed on the holding pedestal 34 (step S31). Then, the plasma doping processing is performed based on a preset doping condition (step S32). Once the plasma doping processing is completed, the processing target substrate W is carried out from the doping apparatus 31 (step S33). Then, the processing target substrate W is put into a washing device, and an SPM washing processing is performed (step S34).

In the doping method according to the first exemplary embodiment, a value of bias electric power used to perform the plasma doping processing in step S32 is set in consideration of the influence on conformality imparted by the SPM washing processing performed after the plasma doping processing.

In the case of performing the SPM washing processing on the processing target substrate after doping, a dopant concentration in each portion of the processing target substrate is not affected equally by the SPM washing processing. First, as a premise, descriptions will be made on the dopant concentration in each portion of a fin of a semiconductor element manufactured by the plasma doping processing.

Dopant Concentration in Each Portion of Fin of Semiconductor Element Subjected to Plasma Doping

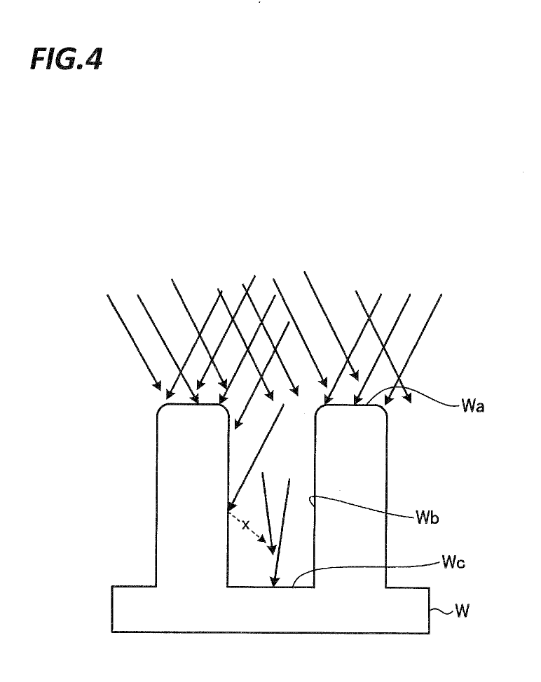

As an example, descriptions will be made on a dopant concentration in a top portion and a side portion of a fin in the case of manufacturing a FinFET type semiconductor element illustrated in FIG. 1 using the plasma doping processing. FIG. 4 is a view illustrating the amount of doping for the FinFET type semiconductor element in the case of performing doping using the plasma doping processing. In the example illustrated in FIG. 4, a processing target substrate W is a FinFET type semiconductor element. Here, when reflection and the like are not considered, fins are provided in the processing target substrate W as illustrated in FIG. 4. As a result, the amounts of radicals and low energy ion components reaching respective portions are different from each other due to a stereoscopic shape. For example, the radicals generated by a radial slot antenna and the low energy ion components inject dopants to top portions Wa of a FinFET upon coming into contact with the top portions Wa thereof. Among the radicals and the low energy ion components that do not come into contact with the top portions Wa of the FinFET, the radicals and the low energy ion components coming into contact with side portions Wb inject dopants to the side portions Wb. Also, among the radicals and the low energy ion components that do not come into contact with the top portions Wa or the side portions Wb of the FinFET, the radicals and the low energy ion components coming into contact with a bottom portion Wc inject dopants to the bottom portion Wc. In other words, as a stereoscopic barrier by the FinFET occurs, the probability of contact with the radicals and the low energy ion components decreases in the order of the top portions Wa, the side portions Wb, and the bottom portion We of the processing target substrate W, and the concentration of injected dopants also decreases accordingly.

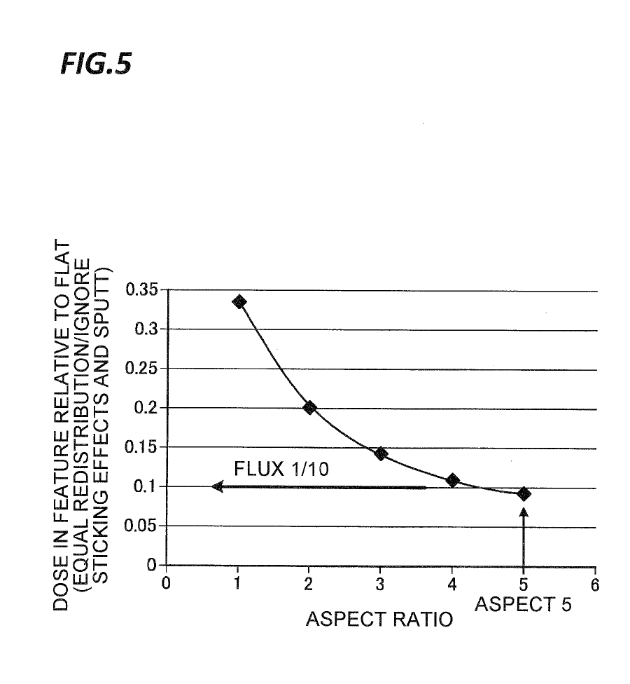

FIG. 5 is a graph illustrating a relative ratio of an aspect ratio in a FinFET type semiconductor element to a concentration of a dopant to be injected. The example illustrated in FIG. 5 represents the case where reflection and the like are not considered. With respect to the dopant concentration illustrated in FIG. 5, As (arsenic) is injected into a silicon substrate. Assuming that the aspect ratio is “1,” that is, a ratio of a length of a top portion to a length of a side surface is “1:1,” as illustrated in FIG. 5, when the concentration of the dopant injected to the top portion is set to “1,” the concentration of the dopant injected to the bottom portion is about “0.35.” Further, assuming that the aspect ratio is “5,” that is, the ratio of the length of the top portion to the length of the side surface is “1:5,” when the concentration of the dopant injected to the top portion is set to “1,” the concentration of the dopant injected to the bottom portion is about “0.1.” As described above, in the case of doping the FinFET type semiconductor element using the plasma doping processing, it is found that it is difficult to perform conformal doping when only the plasma doping processing is performed.

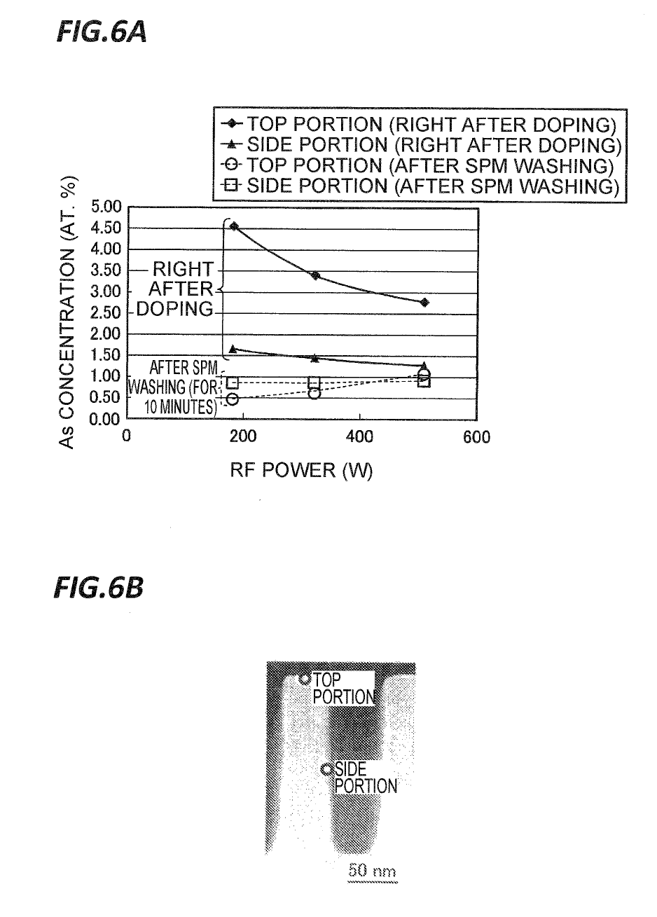

When an SPM washing processing is performed on a processing target substrate W after the plasma doping processing, the dopant concentration in the top portion and the side portion of the fin varies. FIG. 6A is a graph illustrating a relationship among a value of bias electric power supplied in a plasma doping processing (RF power, also called bias electric power), a dopant concentration of a processing target substrate after the plasma doping processing, and the dopant concentration of the processing target substrate after the plasma doping processing and then an SPM washing processing. Further, FIG. 6B is a view illustrating schematic positions of a top portion and a side portion of the FinFET type semiconductor element illustrated in FIG. 6A.

The plasma doping processing used in the example of FIG. 6A is plasma doping using a radial line slot. As a condition of the plasma doping, microwave power was set to 5 kW and a pressure within a processing vessel was set to 230 mTorr. Further, after the total flow rate of a processing gas was set to 1,000 sccm, the flow rate of AsH₃ (0.7%)/He dilution gas was set to 440 sccm. The remaining gas was He gas. The time for performing the plasma doping processing was set to 100 seconds.

Under the above-described plasma doping condition, the plasma doping processing was performed by changing the value of bias electric power applied to a holding pedestal on which a processing target substrate W was disposed, that is, the value of an RF power. Then, the dopant concentration (arsenic concentration) in the top portion and the side portion of a processing target substrate right after the plasma doping processing was measured by a scanning electron microscope/energy dispersive X-ray spectroscope (SEM EDX).

An SPM washing processing was performed on the processing target substrate after the plasma doping processing was performed. As a condition of the SPM washing processing, a mixture of H₂SO₄ (sulfuric acid) and H₂O₂ (hydrogen peroxide water) at a ratio of 4:1 and at a temperature of 110° C. was used, and the washing processing time was set to 10 minutes. Then, the dopant concentration (arsenic concentration) in the top portion and the side portion of the processing target substrate after the SPM washing processing was measured by the SEM EDX.

The dopant concentration measured under the above-described condition is illustrated in FIG. 6A. As illustrated in FIG. 6A, the dopant concentration in the top portion of a fin right after doping becomes higher than the dopant concentration in the side portion of the fin regardless of the value of the RF power. Further, as the RF power applied during the plasma doping processing increases, the dopant concentration in both the top portion and the side portion of the fin decreases. However, the decrease rate in the side portion of the fin is smaller than that in the top portion of the fin.

After the SPM washing processing is performed for 10 minutes, the dopant concentration in the top portion of the fin becomes lower than the dopant concentration in the side portion of the fin when the RF power is about 400 W or less. Meanwhile, when the RF power exceeds about 400 W, the dopant concentration in the top portion of the fin becomes higher than the dopant concentration in the side portion of the fin. From this, it is found that the amount of dopants lost by the SPM washing is greater in the top portion of the fin than the side portion of the fin.

Thus, it is considered that the amount of dopants lost by the SPM washing being smaller in the side portion than in the top portion is due to high chemical resistance, particularly in the side portion of the fin subjected to the plasma doping processing. Therefore, by using the high chemical resistance of the side portion of the FinFET type semiconductor element manufactured by the plasma doping processing, when the RF power is set such that the dopant concentrations in the top portion and the side portion of the semiconductor element after the SPAM washing become equal to each other, conformal doping may be achieved.

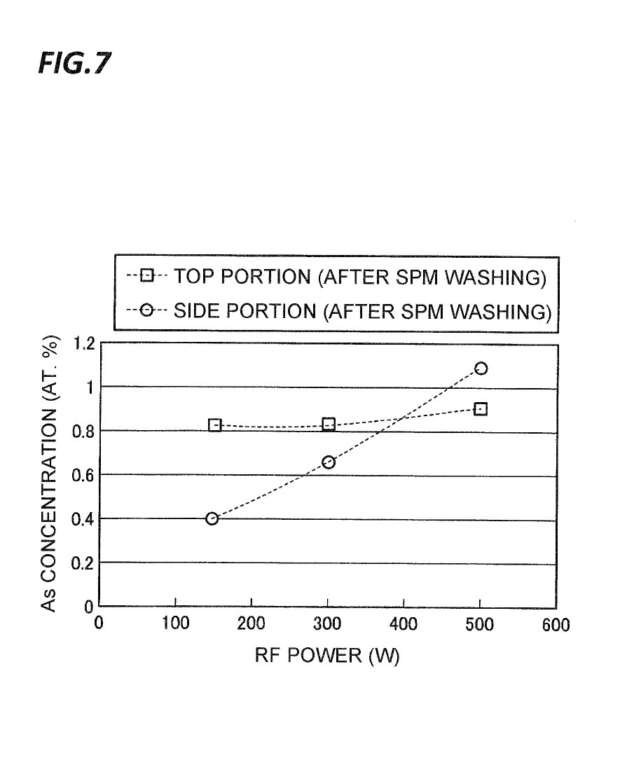

FIG. 7 is a graph illustrating a portion indicating the dopant concentration after the SPM washing in the graph illustrated in FIG. 6A in an enlarged scale. As illustrated in FIG. 7, the dopant concentration in the top portion and the dopant concentration in the side portion after the SPM washing are equal to each other when the RF power is about 400 W. When the value of the RF power applied during the plasma doping is set such that the dopant concentrations in the top portion and the side portion of the semiconductor element after the SPM washing are substantially equal to each other, conformal doping may be achieved by performing the SPM washing after the plasma doping.

Thus, in the example of the doping method illustrated in FIG. 3, tests are performed on the premise that the SPM washing processing is performed by changing an RF power condition in advance and specifying the value of the RF power at which the dopant concentrations in the top portion and the side portion after the SPM washing are substantially equal to each other. Then, the plasma doping processing (step S32) is performed under a condition of the specified value of the RF power.

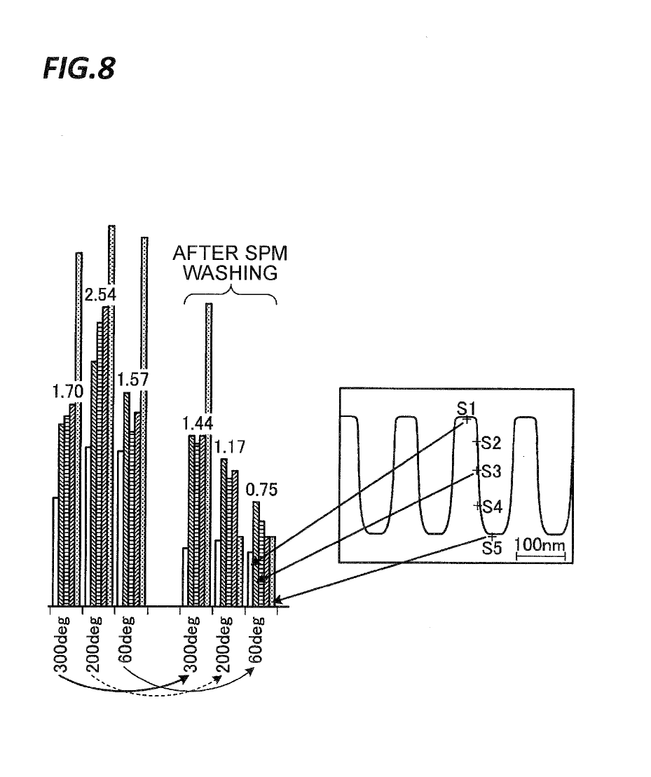

Further, when the SPM washing processing is performed, the dopant concentration may also be adjusted by adjusting the temperature applied to a holding pedestal 34 during the plasma doping processing. FIG. 8 is a graph for explaining a relationship between a temperature applied to the holding pedestal 34 (stage) and a dopant concentration after an SPM washing. The data of FIG. 8 are obtained by changing the temperature applied to the holding pedestal 34 to perform the plasma doping processing and the SPM washing processing. The left side of FIG. 8 represents dopant profiles after the plasma doping processing and after the SPM washing processing in the case of adjusting the temperature of the holding pedestal 34 to 300 degrees, 200 degrees, and 60 degrees, respectively. The dopant concentrations are measured at respective positions of the top portion, the three side portions, and the bottom portion of a fin. The right side of FIG. 8 represents the position of the fin that corresponds to each bar graph in the left side. Further, arsenic is used as a dopant and SEM EDX is utilized for measurement. The SPM washing processing is performed about for 15 minutes. The temperature applied to the holding pedestal 34 may be adjusted using, for example, a temperature adjustment mechanism 29.

From the graph on the left side of FIG. 8, it is found that the dopant profiles right after the plasma doping are hardly affected by the temperature applied to the holding pedestal 34. With regard to this, it is confirmed that, after the SPM washing processing, as the temperature applied to the holding pedestal 34 becomes higher, the dopant concentration at each position becomes substantially higher.

As described above, a chemical residual resistance characteristic of the dopants may be improved by adding a temperature to the holding pedestal 34 to perform the plasma doping processing. The temperature to be applied to the holding pedestal 34 may be about 150 degrees to 600 degrees.

Semiconductor Element Manufacturing Method according to First Exemplary Embodiment

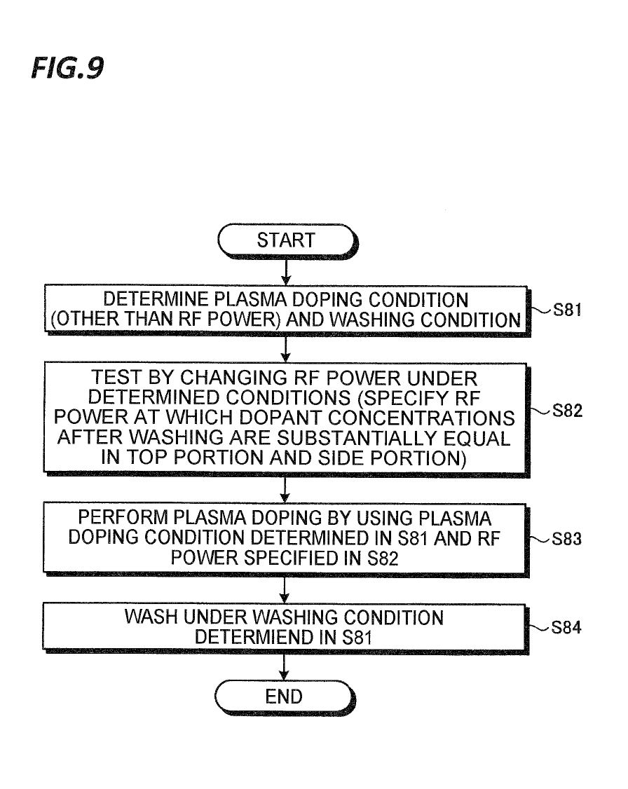

FIG. 9 is a flowchart illustrating a flow of a method for manufacturing a semiconductor element according to the first exemplary embodiment. A semiconductor element manufacturing method illustrated in FIG. 9 may be implemented using the doping apparatus illustrated in FIG. 2 or the doping method illustrated in FIG. 3.

In the semiconductor element manufacturing method according to the first exemplary embodiment, plasma doping conditions for achieving conformal doping, more specifically, an RF power is specified before the plasma doping processing is performed. To this end, plasma doping conditions and washing conditions other than the RF power used for manufacturing the semiconductor element are first determined (step S81). When the conditions of the doping apparatus or the washing device to be used are predetermined, such conditions may be used.

Next, tests are carried out under the predetermined conditions while varying only the value of the RF power applied in the plasma doping processing. Then, the RF power is specified such that the dopant concentration after the washing processing is substantially equal between the top portion and the side portion of the semiconductor element (step S82).

When the RF power is specified, the specified RF power is set as the plasma doping condition, and for the other plasma doping conditions, the plasma doping processing is performed using the plasma doping condition determined in step S81 (step S83). Next, the semiconductor element on which the plasma doping processing is performed is washed using the washing condition determined in step S81 (step S84). Consequently, a conformal semiconductor element having a substantially equal dopant concentration in the top portion and the side portion may be manufactured.

Effect of First Exemplary Embodiment

In the doping method and the doping apparatus according to the first exemplary embodiment as described above, the plasma doping processing is performed on a processing target substrate held on a holding pedestal within a processing vessel by setting a value of bias electric power supplied during the plasma doping processing as a predetermined value on the premise of a washing processing to be performed after the plasma doping, thereby generating plasma within the processing vessel by using microwaves.

According to this doping method, the condition of the plasma doping processing is set by adding the influence of the washing processing to be performed subsequently. Specifically, the value of the RF power is set by adding the influence of the washing processing so that conformal doping after the washing processing may be achieved. Therefore, conformal doping may be easily implemented by performing the washing processing after the plasma doping.

In addition, the semiconductor element manufacturing method according to the first exemplary embodiment includes: an acquiring step of acquiring, as a condition of a plasma doping processing, a predetermined value of bias electric power on the premise of a washing processing to be performed after the plasma doping processing; a plasma doping processing step of performing the plasma doping processing on a processing target substrate while supplying the bias electric power of the predetermined value acquired by the acquiring step; and a washing processing step of performing a washing processing on the processing target substrate on which the plasma doping processing has been performed. Therefore, even when conformal doping is not achieved right after the plasma doping, conformality may be easily achieved by the washing processing to be performed subsequently.

According to the above-described first exemplary embodiment, conformal doping may be implemented by performing the washing processing after the plasma doping processing. Therefore, conformal doping may be achieved even when it is difficult to perform annealing processing exceeding 500° C. right after doping. For example, desired conformality may be achieved even when a mask of, for example, a resist having no heat resistance exists on a doped element. In addition, when a heat treatment is performed right after doping, conformality may be implemented without such concern even when it is concerned that contamination elements may diffuse from the remaining film generated by doping.

Additional effects or modified examples of the above-described exemplary embodiments may be easily conceived by one of ordinary skill in the art. Various exemplary embodiments of the present disclosure have been described in the foregoing, but are not intended to be limiting to the specific and representative exemplary embodiments disclosed herein. Accordingly, various modifications may be made without departing from the scope or spirit of a general inventive concept defined by the following claims and equivalents thereof.

### DESCRIPTION OF SYMBOLS

11: FinFET type semiconductor element
12: silicon substrate
13: main surface
14: fin
15: gate
16: source
17: drain
28: controller
29: temperature adjustment mechanism
30: gas supply hole
31: doping apparatus
32: processing vessel
33: gas supply unit
34: holding pedestal
35: microwave generator
36: dielectric window
37: slot antenna plate
38: dielectric member
39: plasma generation mechanism
40: slot hole

1. A doping method for doping by injecting a dopant into a processing target substrate, the doping method comprising:
a plasma doping processing step including setting a value of bias electric power supplied during a plasma doping processing to a predetermined value on premise of a washing processing to be performed after a plasma doping, and generating plasma within a processing vessel using microwaves so as to perform the plasma doping processing on the processing target substrate held on a holding pedestal in the processing vessel.

2. The doping method of claim 1, wherein, in the plasma doping processing step, the value of the bias electric power is set such that a dopant concentration of a top portion of the processing target substrate and a dopant concentration of a side portion of the processing target substrate are substantially equal to each other when the washing processing is performed after the plasma doping processing.

3. A doping apparatus comprising:
a processing vessel;
a gas supply unit configured to supply a doping gas and an inert gas for plasma excitation to the processing vessel;
a holding pedestal disposed within the processing vessel and configured to hold a processing target substrate thereon;
a plasma generation mechanism configured to generate plasma within the processing vessel using microwaves; and
a controller configured to set a value of bias electric power to a predetermined value on premise of a washing processing to be performed after a plasma doping processing and to control the plasma to be generated within the processing vessel so as to perform the plasma doping processing on the processing target substrate held on the holding pedestal.

4. The doping apparatus of claim 3, further comprising:
a storage unit configured to store, as a condition of the plasma doping processing, a value of bias electric power at which a dopant concentration of a top portion of the processing target substrate and a dopant concentration of a side portion of the processing target substrate are substantially equal to each other when the washing processing is performed after a plasma doping,
wherein the controller controls the plasma generation mechanism to generate the plasma within the processing vessel based on a condition stored in the storage unit so that the plasma doping processing is performed on the processing target substrate held on the holding pedestal.

5. A semiconductor element manufacturing method comprising:
an acquiring step of acquiring, as a condition of a plasma doping processing, a predetermined value of bias electric power on premise of a washing processing to be performed after the plasma doping processing;
a plasma doping processing step of performing the plasma doping processing on a processing target substrate while supplying the predetermined value of bias electric power acquired by the acquiring step; and
a washing processing step of performing the washing processing on the processing target substrate on which the plasma doping processing has been performed.

6. The semiconductor element manufacturing method of claim 5, wherein, in the acquiring step, as the predetermined value, a value of bias electric power is acquired at which a dopant concentration of a top portion of the processing target substrate and a dopant concentration of a side portion of the processing target substrate are substantially equal to each other after the washing processing is performed.

7. The semiconductor element manufacturing method of claim 5, wherein, in the acquiring step, the predetermined value of the bias electric power determined in association with a predetermined condition of the washing processing is acquired, and
the plasma doping processing step is performed while bias electric power in a range of 100 W to 400 W is supplied as the predetermined value.
